(19) United States
(12) Patent Application Publication
(10) Pub. No.: US 2022/0336487 A1
(43) Pub. Date: Oct. 20, 2022

(54) ELECTRONIC DEVICES COMPRISING BLOCKS WITH DIFFERENT MEMORY CELLS, AND RELATED METHODS AND SYSTEMS

(71) Applicant: Micron Technology, Inc., Boise, ID (US)

(72) Inventors: Yifen Liu, Meridian, ID (US); Ching-Huang Lu, Fremont, CA (US); Shuangqiang Luo, Boise, ID (US)

(21) Appl. No.: 17/301,915

(22) Filed: Apr. 19, 2021

(51) Int. Cl. H01L 27/11582; H01L 27/11565; H01L 27/1157

(52) U.S. Cl. CPC H01L 27/11582; H01L 27/11565; H01L 27/1157

(57) ABSTRACT

An electronic device comprising first blocks and second blocks of an array comprising memory cells. The memory cells in the first and second blocks comprise memory pillars extending through a stack. The memory pillars comprise a charge blocking material laterally adjacent to the stack, a storage nitride material laterally adjacent to the charge blocking material, a tunnel dielectric material laterally adjacent to the storage nitride material, a channel material laterally adjacent to the tunnel dielectric material, and a fill material between opposing sides of the channel material. One or more of the storage nitride material and the tunnel dielectric material in the first blocks differ in thickness or in material composition from one or more of the storage nitride material and the tunnel dielectric material in the second blocks. Additional electronic devices are disclosed, as are methods of forming an electronic device and related systems.

### TECHNICAL FIELD

Embodiments disclosed herein relate to electronic devices and electronic device fabrication. More particularly, embodiments of the disclosure relate to electronic devices comprising blocks with memory cells configured to exhibit different electrical properties on a single die and to related methods and systems.

### BACKGROUND

Electronic device (e.g., semiconductor device, memory device) designers often desire to increase the level of integration or density of features (e.g., components) within an electronic device by reducing the dimensions of the individual features and by reducing the separation distance between neighboring features. Electronic device designers also desire to design architectures that are not only compact, but offer performance advantages, as well as simplified designs. Reducing the dimensions and spacing of features has placed increasing demands on the methods used to form the electronic devices. One solution has been to form three-dimensional (3D) electronic devices, such as 3D NAND devices, in which memory cells are stacked vertically on a substrate.

3D NAND devices may include single level cell (SLC) blocks, which store one bit of data, and multilevel cell (MLC) blocks, which store multiple bits per cell. The MLC blocks may include triple level cells (TLC) blocks or quad level cells (QLC) blocks. A single 3D NAND device includes SLC blocks and MLC blocks in a single die, with the SLC blocks and MLC blocks present in the same memory array. The SLC blocks are used for shorter term storage of data and the MLC blocks are used for longer term storage of data. Data is written into the SLC blocks, accumulated, and programmed into the MLC blocks. Since all of the data goes through the SLC blocks, the SLC blocks are programmed and erased (e.g., cycled) orders of magnitude more times than the MLC blocks. The SLC blocks, therefore, have more stringent requirements for endurance and data retention properties than the MLC blocks, such as needing higher cycling capability and endurance than the MLC blocks. The SLC blocks and the MLC blocks also have different reliability requirements since electronic data in the MLC blocks are more densely packed than electronic data in the SLC blocks and electronic systems may use SLC and MLC blocks with different frequency. However, achieving a desired balance in properties between the SLC blocks and the MLC blocks is difficult because improving one property often negatively affects another property.

### BRIEF DESCRIPTION OF THE DRAWINGS

FIG. 1 is a cross-sectional view of an electronic device including different memory cells in different blocks of a single die according to embodiments of the disclosure;

FIG. 2 is an electronic device including different memory cells in different blocks of a single die according to embodiments of the disclosure;

FIGS. 3-9 are cross-sectional views that illustrate forming the electronic device of FIG. 1 according to embodiments of the disclosure;

FIGS. 10-14 are cross-sectional views that illustrate forming the electronic device of FIG. 2 according to embodiments of the disclosure

FIG. 15 is a partial, cutaway, perspective, schematic illustration of an apparatus including one or more electronic devices in accordance with embodiments of the disclosure;

FIG. 16 is a functional block diagram of a memory array including one or more electronic devices according to embodiments of the disclosure; and

FIG. 17 is a simplified block diagram of a system including one or more electronic devices according to embodiments of the disclosure.

### DETAILED DESCRIPTION

An electronic device (e.g., an apparatus, a semiconductor device, a memory device) that includes different memory cells in different (e.g., separate) blocks of a single die is disclosed. The die (e.g., integrated circuit) includes the different memory cells in first and second blocks. The memory cells in the different blocks differ in a thickness of a particular cell material, in a composition of a particular cell material, or in both a thickness and a composition of a particular cell material. The cell material that differs between the blocks of a single die may be one or more of a charge blocking material, a storage nitride material, or a tunnel dielectric material. The difference in property (e.g., thickness, composition) of the cell material in the memory cells of a first block and of a second block of the electronic device enables the memory cells in the first and second blocks to exhibit different electrical performance properties during use and operation of the electronic device. For instance, one or more of the charge blocking material, the storage nitride material, or the tunnel dielectric material of the memory cells may differ in thickness between the first and second blocks of the electronic device. Alternatively, the memory cells may differ in thickness and material composition of the particular cell material (e.g., one or more of the charge blocking material, the storage nitride material, the tunnel dielectric material) in the first and second blocks of the electronic device. A single die that includes the different memory cells in the first blocks and the second blocks of the electronic device may exhibit different electrical properties of the memory cells in the first and second blocks. The first and second blocks of the electronic device may be configured to exhibit different electrical properties to achieve the desired overall electrical properties of the die containing the electronic devices having the different memory cells.

Methods of forming the electronic device are also disclosed. By forming the first blocks and the second blocks of the electronic device to include the different memory cells, the memory cells in the first blocks and the second blocks exhibit different electrical properties, such as cycling or reliability properties. The first blocks and the second blocks are exposed to different process conditions to form the different memory cells in the first blocks and the second blocks of a single die. The methods of forming the electronic device according to embodiments of the disclosure produce the different memory cells without adding complex process acts to the overall formation of the electronic device. The methods of forming the electronic device may also be compatible with conventional process acts, enabling cost effective fabrication of the electronic device.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization (CMP)), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “block” means and includes a number of memory pillars in the electronic device that are configured to be programmable and erasable at a particular time. The electronic device includes an array of memory pillars in repeated block units. The memory pillars in each block of the electronic device are programmable at different times during use and operation of the electronic device. The number of memory pillars in each block may be on the order of thousands or greater and are not limited to any specific number.

As used herein, the term “cell material” means and includes a charge blocking material, a storage nitride material, or a tunnel dielectric material of a pillar region (e.g., a memory pillar region) of the electronic device. The pillar region also includes a channel material and a fill material.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operably connected with each other, such as electrically connected through a direct ohmic connection or through an indirect connection (e.g., via another structure).

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), doped SiOₓ, phosphosilicate glass, borosilicate glass, borophosphosilicate glass, fluorosilicate glass, tetraethylorthosilicate (TEOS), aluminum oxide (AlOₓ), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrOₓ), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the term “different cell material” means and includes a difference in thickness, in composition, or in thickness and composition of a particular cell material in one block from the same type of cell material in another block.

As used herein, the term “different memory cells” means and includes memory cells in separate blocks of the electronic device that differ in a thickness of a cell material, in a composition of a cell material, or in a thickness and a composition of a cell material. The different memory cells of the electronic device are in a single die, a single integrated circuit, or a single memory array.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “stacks” means and includes a feature having one or more materials vertically adjacent to one another. The stacks may include alternating dielectric materials and conductive materials, such as alternating oxide materials and metal materials or alternating oxide materials and polysilicon materials. Depending on the stage of fabrication of the electronic structure containing the stacks, the stacks may alternatively include alternating dielectric materials and nitride materials, such as alternating oxide materials and silicon nitride materials.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

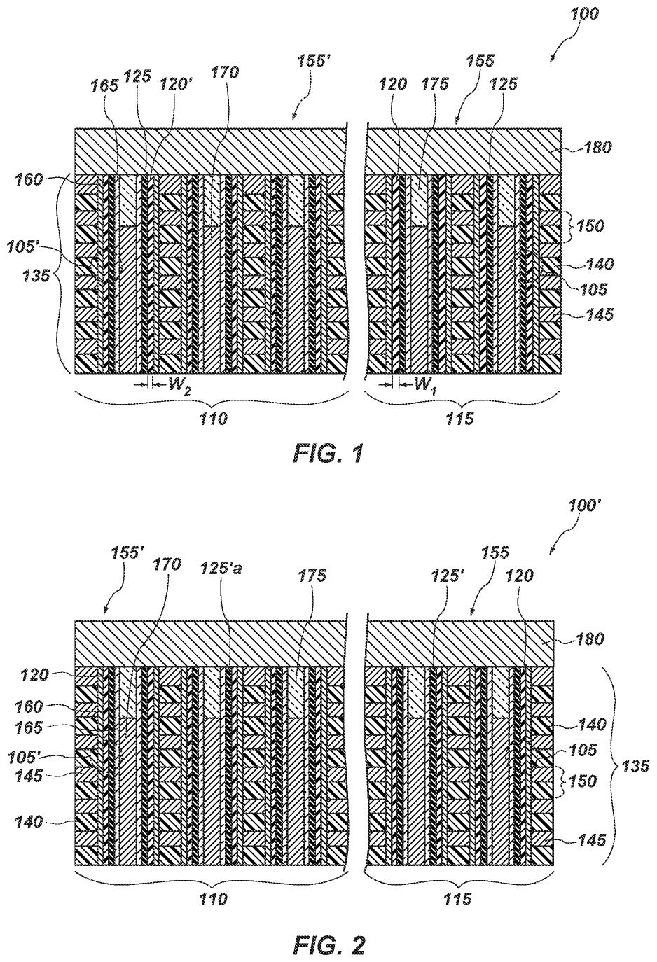

As shown in FIGS. 1 and 2, electronic devices 100, 100′ according to embodiments of the disclosure include memory cells 105, 105′ that are configured to exhibit different electrical properties in a first block 110 and a second block 115 of the electronic devices 100, 100′. The difference in cell material properties in the first block 110 and in the second block 115 enable the electronic devices 100, 100′ to exhibit different endurance and reliability properties in the first block 110 and the second block 115. The different electrical properties may be due to different thicknesses of one or more of the cell film materials (FIG. 1) of the memory cells 105, 105′ in the first block 110 and in the second block 115 or due to different material compositions and thicknesses of one or more of the cell film materials (FIG. 2) of the memory cells 105, 105′ in the first block 110 and in the second block 115. The first blocks 110 and the second blocks 115 may be configured as single level cell (SLC) blocks or multilevel cell (MLC) blocks ((e.g., triple level cells (TLC), quad level cells (QLC)). In some embodiments, the first blocks 110 are configured as TLC blocks and the second blocks 115 are configured as SLC blocks. In other embodiments, the first blocks 110 are configured as QLC blocks and the second blocks 115 are configured as SLC blocks. While FIGS. 1 and 2 illustrate two blocks of the electronic devices 100, 100′, more than two blocks may be present depending on the desired electrical properties of the electronic devices 100, 100′. The electronic devices 100, 100′ may also include a combination of SLC blocks, TLC blocks, and QLC blocks.

For example, a thickness of a charge blocking material 160, of a storage nitride material 120, or of a tunnel dielectric material 125 may be different in the first block 110 and in the second block 115 of the electronic device 100. The electronic device 100 may, for example, include a thinner (e.g., less thick) particular cell material in the first block 110 than in the second block 115. By way of example only and as shown in FIG. 1, the storage nitride materials 120, 120′ of the cell materials may differ in thickness, indicated by W₁ and W₂, between the first block 110 and the second block 115. Alternatively or in addition, the charge blocking material 160 or the tunnel dielectric material 125 of the memory cells 105′ may differ in thickness between the first block 110 and the second block 115. While the embodiments described and illustrated herein show that the first block 110 includes a thinner, particular cell material than the second block 115, the electronic device 100 may, for example, include a thicker (e.g., less thin), particular cell material in the first block 110 than in the second block 115. The different relative thicknesses of the particular cell material in the first block 110 and the second block 115 refers to an average thickness of that cell material since a small variation in thickness may occur during formation of the cell material due to process limitations of forming the particular cell material.

The different electrical properties may also be due to differences in material compositions and to different thicknesses of one or more of the cell materials in the first block 110 and in the second block 115. For example, the material compositions and thicknesses of the charge blocking material 160, of the storage nitride material 120, or of the tunnel dielectric material 125 may differ between the first block 110 and in the second block 115. By way of example only and as shown in FIG. 2, the first block 110 and the second block 115 of the memory cells 105 may include tunnel dielectric materials 125′, 125′a of different material compositions and of different thicknesses. Alternatively or in addition, the material compositions and thicknesses of the charge blocking material 160 or of the storage nitride material 120 of the memory cells 105 may differ between the first block 110 and the second block 115. While the embodiments described and illustrated herein show that the first block 110 includes the cell material exhibiting the different material composition and different thickness, the electronic device 100′ may, for example, include the cell material exhibiting the different material composition and different thickness in the second block 115.

The stack 135 of alternating dielectric materials 145 and conductive materials 140 defines a cell region of the electronic devices 100, 100′ and the cell materials define a pillar region of the electronic devices 100, 100′. The cell materials may include the charge blocking material, the storage nitride material, the tunnel dielectric material, the channel material 165, and the fill material 170 of the pillar region (e.g., a memory pillar region) of the electronic devices 100, 100′. The pillar region of the first block 110 is adjacent to (e.g., laterally adjacent to) the cell region of the first block 110 and the pillar region of the second block 115 is adjacent to (e.g., laterally adjacent to) the cell region of the second block 115. A particular pillar region is positioned between two cell regions and a particular cell region is positioned between two pillar regions. The pillar region includes pillars 155, 155′ of the cell materials.

The charge blocking material 160 (also known as a block oxide material) may include, but is not limited to, silicon dioxide, aluminum oxide, hafnium oxide, zirconium oxide, or a combination thereof. In some embodiments, the charge blocking material 160 is silicon dioxide. The storage nitride material 120 may include, but is not limited to, silicon nitride, silicon oxynitride, or a combination thereof. In some embodiments, the storage nitride material 120 is silicon nitride. The tunnel dielectric material 125 may include, but is not limited to, silicon dioxide, silicon nitride, aluminum oxide, hafnium oxide, zirconium oxide, or a combination thereof. By way of example only, the tunnel dielectric material 125 may be a so-called “oxide-nitride-oxide” (ONO) structure (e.g., an interlayer silicon based dielectric structure). In some embodiments, the tunnel dielectric material 125 is silicon nitride or silicon oxynitride. In other embodiments, the tunnel dielectric material 125 is silicon nitride and includes a silicon-rich portion. In yet other embodiments, the tunnel dielectric material 125 is silicon oxynitride and includes a silicon-rich portion.

The first blocks 110 and the second blocks 115 of the electronic devices 100, 100′ include stacks 135 of alternating conductive materials 140 and dielectric materials 145. The stacks 135 include tiers 150, with each tier 150 including a single conductive material 140 and a single dielectric material 145. The stacks 135 may include multiple tiers of the alternating tier dielectric materials 145 and the tier conductive materials 140, such as greater than or equal to 50 tiers 150, greater than or equal to 100 tiers 150, greater than or equal to 200 tiers 150, or greater than or equal to 500 tiers 150. The pillars 155 (e.g., memory pillars) of the memory cells 105, 105′ include the charge blocking material 160, the storage nitride material 120, 120′, the tunnel dielectric material 125′, 125′a, the channel material 165, and the fill material 170. For simplicity in the drawings, only a few pillars 155 in each of the first and second blocks 110, 115 are illustrated, with a break line between the first and second blocks 110, 115 indicating that additional pillars 155 may be present. As shown in FIG. 1, the charge blocking material 160 may be adjacent to (e.g., laterally adjacent to) the alternating conductive materials 140 and dielectric materials 145, the storage nitride material 120, 120′ may be adjacent to (e.g., laterally adjacent to) the charge blocking material 160, and the tunnel dielectric material 125 may be adjacent to (e.g., laterally adjacent to) the storage nitride material 120, 120′. As shown in FIG. 2, the charge blocking material 160 may be adjacent to (e.g., laterally adjacent to) the alternating conductive materials 140 and dielectric materials 145, the storage nitride material 120 may be adjacent to (e.g., laterally adjacent to) the charge blocking material 160, and the tunnel dielectric material 125′, 125′a may be adjacent to (e.g., laterally adjacent to) the storage nitride materials 120, 120′.

In both FIGS. 1 and 2, the channel material 165 may be adjacent to (e.g., laterally adjacent to) the tunnel dielectric material 125 and the fill material 170 may be adjacent to (e.g., laterally adjacent to) the channel material 165. The channel material 165 may include, but is not limited to, doped polysilicon, undoped polysilicon, or other channel material. In some embodiments, the channel material is polysilicon. The charge blocking material, the storage nitride material, and the tunnel dielectric material are coextensive with a height of the stack 135. The channel material 165 is coextensive with the height of the stack 135. The fill material 170 may be a dielectric material including, but not limited to, silicon dioxide, phosphosilicate glass, borosilicate glass, borophosphosilicate glass, fluorosilicate glass, titanium dioxide, hafnium oxide, zirconium dioxide, tantalum oxide, magnesium oxide, aluminum oxide, or a combination thereof. The fill material 170 may be recessed in the stacks 135 and a conductive material 175 (e.g., a plug material) may be adjacent to (e.g., vertically adjacent to) the fill material 170. A cap material 180 may be adjacent to (e.g., vertically adjacent to) the stack 135 and the pillars 155. While illustrated in FIGS. 1 and 2, the cap material 180 is removed during subsequent process acts such that desired electrical connections between the pillars 155 and overlying contacts (not shown) are achieved.

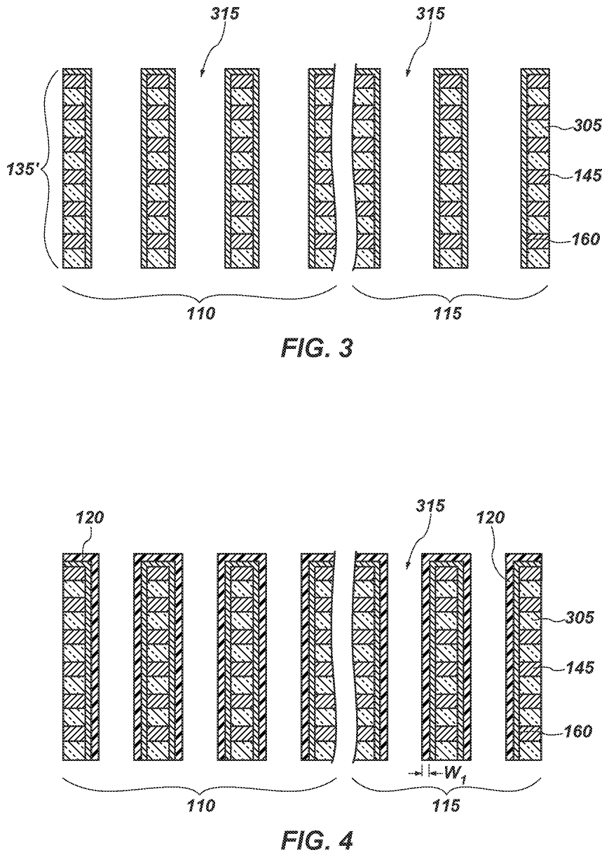

To form the electronic device 100, a stack 135′ that includes alternating tier dielectric materials 145 and tier nitride materials 305 and pillar openings 315 is formed, as shown in FIG. 3. The tier dielectric materials 145 and tier nitride materials 305 are referred to collectively as tier dielectric materials 310 and are formed by conventional techniques. A region of the stack 135′ corresponds to the first block 110 (e.g., MLC block) and a region of the stack 135′ corresponds to the second block 115 (e.g., SLC block). The pillar openings 315 are formed through the tier dielectric materials 145 and tier nitride materials 305 in the first block 110 and second block 115 by conventional techniques. The pillar openings 315 may be high aspect ratio openings that extend through the tier dielectric materials 310. While three pillar openings 315 in the first block 110 and two pillar openings 315 in the second block 115 are illustrated in FIG. 3, additional pillar openings 315 may be formed in the first block 110 and the second block 115.

The charge blocking material 160 of the cell materials is formed in the pillar openings 315. The charge blocking material 160 may be formed on sidewalls of the tier dielectric materials 310 and the tier nitride materials 305. The charge blocking material 160 may be formed by conventional techniques, such as by a conformal deposition process. In some embodiments, the charge blocking material 160 is formed by ALD. The charge blocking material 160 may be formed to a desired thickness such that a portion of the pillar openings 315 remains unfilled (e.g., open). In other words, only a portion of the pillar openings 315 is occupied by the charge blocking material 160. The charge blocking material 160 of the first block 110 and the second block 115 may be formed to the same thickness. By way of example only, the charge blocking material 160 may be formed at a thickness of from about 5 nm to about 15 nm, such as from about 5 nm to about 10 nm, from about 7 nm to about 12 nm, or from about 6 nm to about 10 nm.

As shown in FIG. 4, the storage nitride material 120 is formed in the pillar openings 315, adjacent to (e.g., laterally adjacent to) the charge blocking material 160 and an upper surface of the stack 135. The storage nitride material 120 may be conformally formed on sidewalls of the charge blocking material 160 and on the upper surface of the stack 135. The storage nitride material 120 may be formed by conventional techniques. In some embodiments, the storage nitride material 120 is formed by ALD. The storage nitride material 120 may be formed to a desired thickness, indicated as W₁. The thickness of the storage nitride material 120 as formed may be substantially the same in the first block 110 and in the second block 115. By way of example only, the as-formed storage nitride material 120 may be formed at a thickness of from about 5 nm to about 15 nm, such as from about 7 nm to about 15 nm, from about 7 nm to about 12 nm, from about 8 nm to about 12 nm, or from about 6 nm to about 9 nm. Depending on a desired thickness of the storage nitride material 120, 120′ in the first and second blocks 110, 115 of the electronic device 100, a portion of the as-formed storage nitride material 120 may optionally be removed (e.g., trimmed) from the first and second blocks 110, 115 at the process stage shown in FIG. 4 before conducting additional process acts. The optional portion of the as-formed storage nitride material 120 may be removed by conventional techniques.

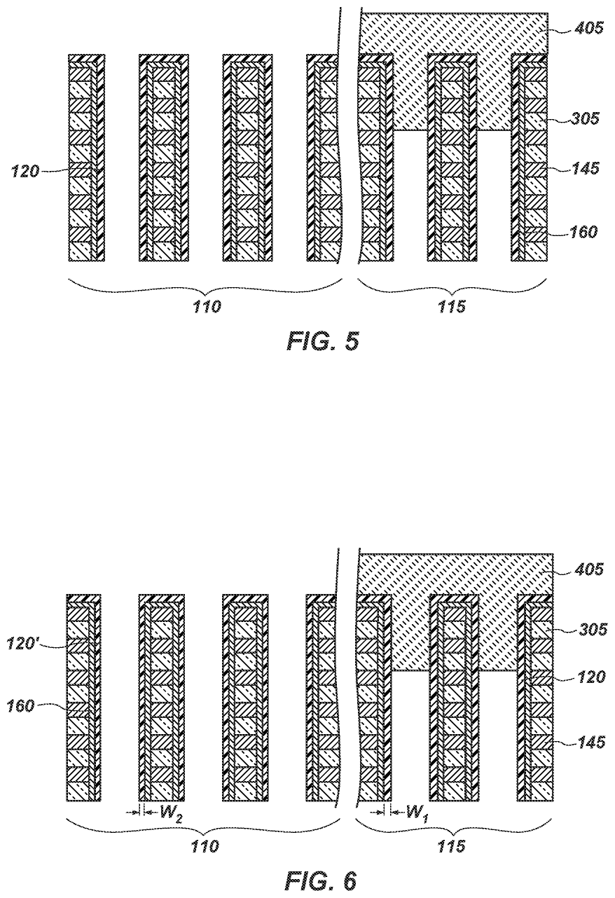

A portion of the storage nitride material 120 of the first block 110 is then removed, as shown in FIGS. 5 and 6, so that the storage nitride material 120′ of the first block 110 has a different thickness W₂ than the thickness W₁ of the storage nitride material 120 of the second block 115. The storage nitride material 120 of the second block 115 may, for example, be thicker than the storage nitride material 120′ of the first block 110. A mask 405 is formed over the second block 115 to protect the storage nitride material 120 of the second block 115, as shown in FIG. 5. The mask 405 may function, for example, as a masking material, a masking region, a cap material, or a cap region. The mask 405 may be formed of a resist material or a carbon material by conventional techniques. The mask 405 protects the cell materials of the second block 115 while the storage nitride material 120 within the pillar openings 315 of the first block 110 is exposed to etch conditions that remove the desired portion of the storage nitride material 120′, as shown in FIG. 6. The storage nitride material 120 of the first block 110 may, for example, be exposed to a wet etch process. The storage nitride material 120 of the first block 110 may be removed by conventional techniques, such as by exposing the storage nitride material 120 to a dilute HF solution or by using a vapor etch process. By adjusting one or more of etchant concentration, temperature, flow rate, time, pressure, dispersion method (immersion, spraying, etc.) of the etch conditions, from about 1 nm to about 4 nm of the storage nitride material 120 of the first block 110 may be removed. For example, from about 1 nm to about 3 nm or from about 2 nm to about 4 nm of the storage nitride material 120 may be removed to form the storage nitride material 120′. The storage nitride material 120′ of the first block 110 is, therefore, thinner than the storage nitride material 120 of the second block 115. In other words, the thickness W₂ of the storage nitride material 120′ is less than the thickness W₁ of the storage nitride material 120. A difference in thickness between the storage nitride material 120′ of the first block 110 and the storage nitride material 120 of the second block 115 may, for example, be between about 1 nm and about 3 nm. By adjusting the process conditions of the wet etch process, the difference in thickness between the storage nitride material 120′ of the first block 110 and the storage nitride material 120 of the second block 115 may be easily tailored.

If the optional portion of the as-formed storage nitride material 120 is removed at the process stage shown in FIG. 4, a different etch chemistry may be used to conduct this removal than the etch chemistry used to form the storage nitride material 120′. By way of example only, the optional removal of the storage nitride material 120 may be conducted using a relatively fast and cheap wet etch process while a slower, more controllable wet etch process may be used to form the storage nitride material 120′. The more controllable, wet etch process may, for example, enable surface roughness of the storage nitride material 120′ to be controlled.

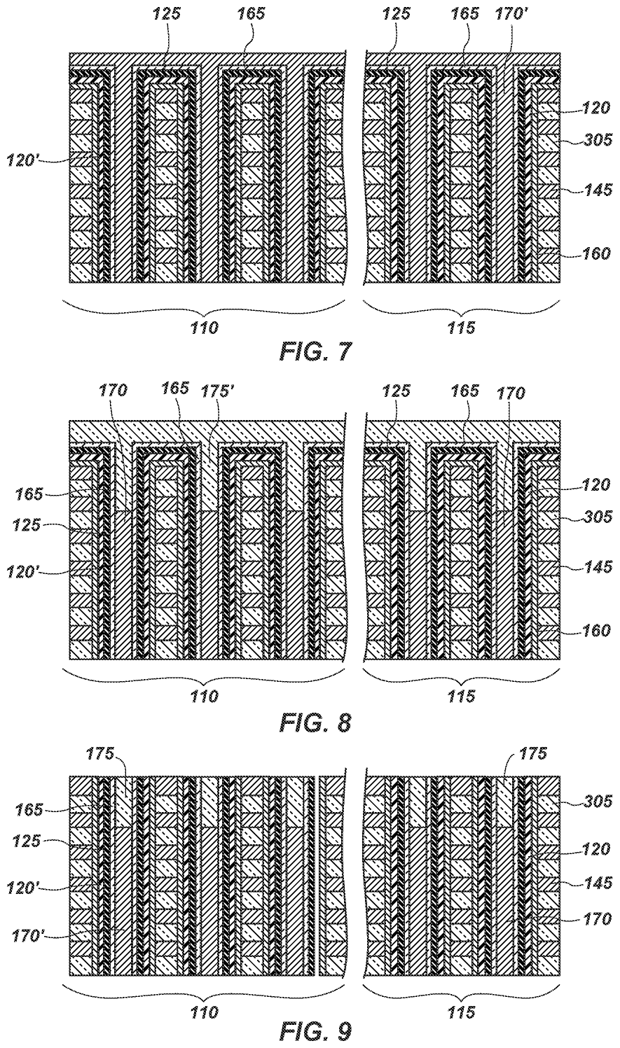

The mask 405 may be removed and remaining materials of the cell materials formed in the pillar openings 315, as shown in FIG. 7. The mask 405 may be removed by conventional techniques. The tunnel dielectric material 125 is formed in the pillar openings 315 and adjacent to (e.g., laterally adjacent to) the storage nitride material 120, the channel material 165 is formed adjacent to (e.g., laterally adjacent to) the tunnel dielectric material 125, and the fill material 170′ is formed adjacent to (e.g., laterally adjacent to) the channel material 165. The tunnel dielectric material 125 and the channel material 165 may be sequentially formed in the pillar openings 315 and adjacent to (e.g., over) the upper surface of the stack 135. The tunnel dielectric material 125 may be conformally formed on sidewalls of the storage nitride material 120 and the channel material 165 may be conformally formed on sidewalls of the tunnel dielectric material 125. The tunnel dielectric material 125 and the channel material 165 may be formed at desired thicknesses. By way of example only, each of the tunnel dielectric material 125 and the channel material 165 may be formed at a thickness of from about 5 nm to about 15 nm, such as from about 7 nm to about 15 nm, from about 7 nm to about 12 nm, from about 8 nm to about 12 nm, or from about 6 nm to about 9 nm. The fill material 170′ is formed in remaining portions of the pillar openings 315 and adjacent to (e.g., over) the upper surface of the stack 135. The tunnel dielectric material 125, the channel material 165, and the fill material 170′ may be formed by conventional techniques.

A portion of the fill material 170′ is removed, recessing the fill material 170 in the pillar openings 315, as shown in FIG. 8. The fill material 170′ may be removed by conventional techniques, such as by a wet or vapor etch process. A conductive material 175′ is formed in the pillar openings 315 and adjacent to (e.g., over) the upper surface of the stack 135. The conductive material 175′ may be formed adjacent to (e.g., over) the fill material 170 and on sidewalls of the channel material 165. The conductive material 175′ may, for example, be polysilicon. A portion of the conductive material 175′ and the cell materials (e.g., the tunnel dielectric material 125, the channel material, the storage nitride material 120, 120′) may be removed from the upper surface of the stack 135, such as by an abrasive planarization process, as shown in FIG. 9. The conductive material 175 may function as a conductive plug over the fill material 170. As shown in FIGS. 6-9, the storage nitride material 120, 120′ exhibit different thicknesses in the first block 110 and in the second block 115.

The tier nitride materials 305 of the stack 135 may be removed and replaced with tier conductive materials 140 to form the electronic device 100 including the storage nitride material 120, 120′ of different thicknesses in the first block 110 and second block 115, as shown in FIG. 1. The tier nitride materials 305 are removed and replaced with the tier conductive materials 140 by a so-called “replacement gate” process. A slit (not shown) is formed through the stack 135 and a wet etch process is conducted to remove the tier nitride materials 305 through the slit. The tier nitride materials 305 may be removed by exposing the tier nitride materials 305 to a wet etch process, such as a so-called “wet nitride strip” process. The tier conductive materials 140 are formed in openings (not shown) formed by the removal of the tier nitride materials 305. A liner (not shown) may, optionally, be formed in the openings before forming the tier conductive materials 140. Therefore, the alternating dielectric materials 145 and tier nitride materials 305 are converted to the alternating dielectric materials 145 and tier conductive materials 140 of the electronic device 100. The electronic device 100 (FIG. 1), therefore, includes the memory cells 105, 105′ with the different thicknesses in the first block 110 and in the second block 115.

Since the first block 110 (e.g., the MLC block) includes the thinner storage nitride material 120′ and the second block 115 (e.g., the SLC block) includes the thicker storage nitride material 120, improved cycling and retention properties of the memory cells 105 of the SLC block may be achieved relative to the memory cells 105′ of the MLC block. The memory cells 105, 105′ may, therefore, be tailored in the first block 110 and in the second block 115 to achieve more stringent cycling and retention properties in the memory cells 105 of the SLC block than the memory cells 105′ of the MLC block. By exposing the first block 110 and the second block 115 to different process conditions, the different memory cells 105, 105′ according to embodiments of the disclosure in the first block 110 and the second block 115 of a single die are formed. In contrast, conventional methods of forming memory cells expose the memory cells in different blocks to the same process conditions.

While the process above describes producing the storage nitride material 120′ in the first block 110 to be thinner than the storage nitride material 120 in the second block 115, the relative thicknesses of the storage nitride material 120, 120′ may be reversed, with the storage nitride material 120′ in the first block 110 being thicker than the storage nitride material 120 in the second block 115. In addition, more than one mask formation and mask removal acts may be conducted to form additional, different thicknesses of the storage nitride material 120 in the blocks, such as in the first and second blocks 110, 115. For instance, two or more mask formation and mask removal acts may be conducted to produce three or more thicknesses of the storage nitride material 120 in different blocks of the electronic devices 100, 100′. For example, if the electronic devices 100, 100′ include three different blocks, such as first blocks 110, second blocks 115, and third blocks (not shown), the thicknesses of the storage nitride material 120 in each of the blocks may be different by conducting two or more mask formation and mask removal acts.

The different electrical properties may, alternatively, be due to differences in the material compositions and thicknesses of one or more of the cell materials in the first block 110 and in the second block 115. For example, the material compositions and thicknesses of the charge blocking material 160, of the storage nitride material 120, or of the tunnel dielectric material 125 may differ between the first block 110 and the second block 115 of the electronic device 100′ (FIG. 2). The material compositions may differ in relative amounts (e.g., concentrations) of one or more of the elements (e.g., chemical elements) of the cell film material. By way of example only, the storage nitride material 120′ of the first block 110 may include a stoichiometric compound of the material while 120 of the second block 115 may similarly include a stoichiometric compound of the material or a less than stoichiometric compound of the material. By way of example only, the tunnel dielectric material 125′, 125′a may differ in silicon content if the tunnel dielectric material 125′, 125′a is formed of silicon nitride or of silicon oxynitride. Alternatively, the material compositions may differ in that different chemical elements may be present in the tunnel dielectric material 125′, 125′a. By way of example only, the tunnel dielectric material 125′ may include silicon nitride and the tunnel dielectric material 125′a may include silicon oxynitride. Alternatively, the tunnel dielectric material 125′ may be a substantially homogeneous silicon nitride material or a substantially homogeneous silicon oxynitride material while the tunnel dielectric material 125′a may be a heterogeneous silicon nitride material or a heterogeneous silicon oxynitride material. The heterogeneous silicon nitride or heterogeneous silicon oxynitride of the tunnel dielectric material 125′a may include a portion that differs in relative amount (e.g., concentration) of one or more of the elements (e.g., chemical elements) from the tunnel dielectric material 125′. By way of example only, the tunnel dielectric material 125′a may include a gradient of one or more of the elements across its thickness of one or more of the elements or may include a portion thereof having a different relative amount (e.g., concentration) of one or more of the elements. In some embodiments, the tunnel dielectric material 125′, 125′a is silicon nitride or silicon oxynitride. In other embodiments, the tunnel dielectric material 125′, 125′a is silicon nitride or silicon oxynitride and further includes an oxidized portion of the silicon nitride or the silicon oxynitride.

To form the electronic device 100′, the charge blocking material 160 and storage nitride material 120 of the first block 110 and the second block 115 are formed on the stack 135 as described above for FIGS. 3 and 4. The tunnel dielectric material 125 may be formed adjacent to (e.g., laterally adjacent to) the storage nitride material 120, as shown in FIG. 10. The tunnel dielectric material 125 may, for example, be conformally formed over sidewalls and upper surfaces of the storage nitride material 120. At the process stage shown in FIG. 10, each of the respective charge blocking material 160, the storage nitride material 120, and the tunnel dielectric material 125 exhibits a material composition that is substantially the same in both the first block 110 and in the second block 115, and each of the respective charge blocking material 160, the storage nitride material 120, and the tunnel dielectric material 125 exhibits a thickness that is substantially the same in both the first block 110 and in the second block 115. The materials used and thicknesses of each of the charge blocking material 160, the storage nitride material 120, and the tunnel dielectric material 125 may be as described above for FIGS. 3-7.

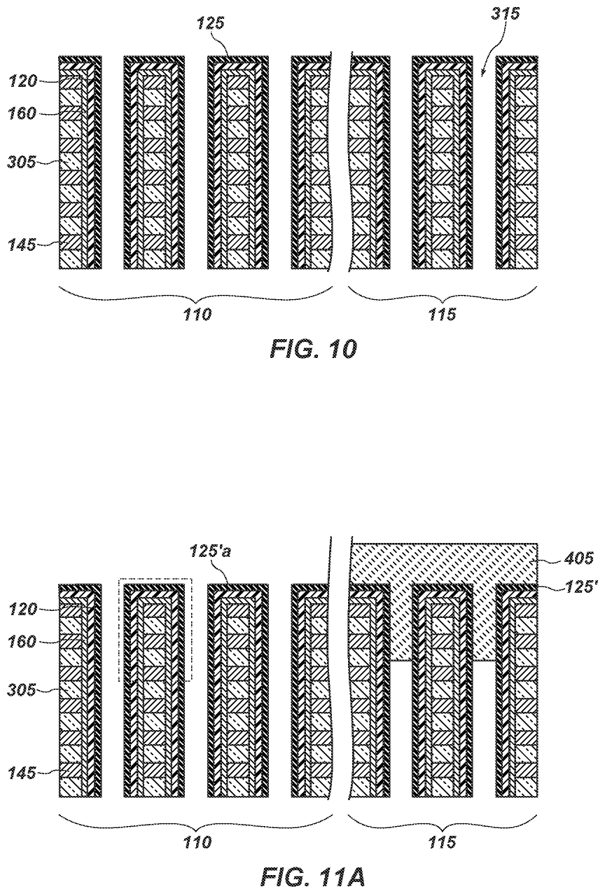

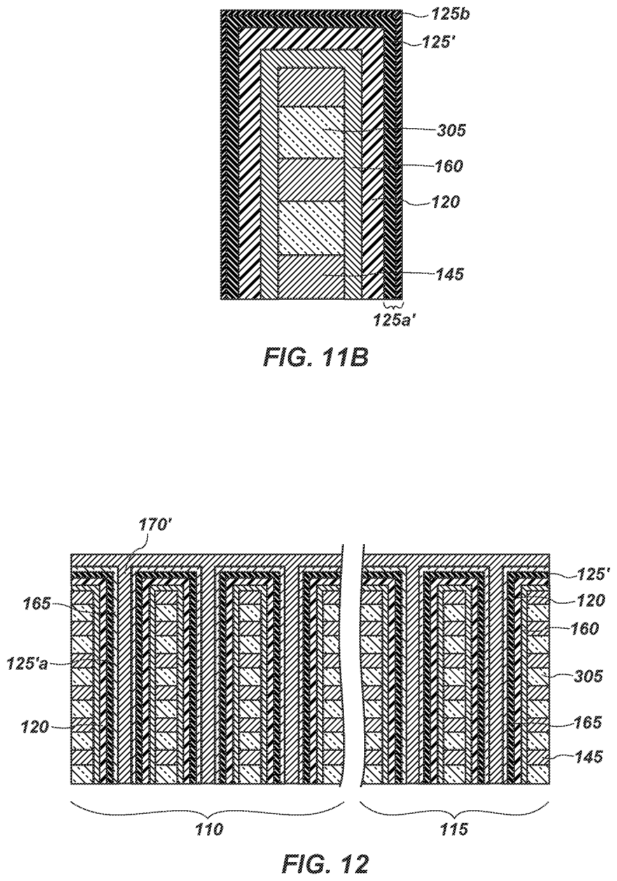

An oxidation process is conducted, during which the tunnel dielectric material 125 is exposed to conditions that oxidize a portion of the tunnel dielectric material 125 and form the tunnel dielectric material 125′, as shown in FIGS. 11A and 11B. The oxidation process may include, but is not limited to, a radical oxidation process, a steam oxidation process, or a water vapor oxidation process. The oxidation process oxidizes an upper portion of the tunnel dielectric material 125 of the first and second blocks 110, 115 to a desired depth, producing the tunnel dielectric material 125′. If, for example, the tunnel dielectric material 125 is formed of silicon oxynitride, a portion of the tunnel dielectric material 125 is converted to silicon oxide by the oxidation process, forming the tunnel dielectric material 125′ including the upper portion of silicon oxide. Similarly, if the tunnel dielectric material 125 is formed of silicon nitride, a portion of the tunnel dielectric material 125 is converted to silicon oxide by the oxidation process, forming the tunnel dielectric material 125′ including the upper portion of silicon oxide.

Following the oxidation process, the tunnel dielectric material 125′ of the first block 110 and the second block 115 exhibit the same material composition and the same thickness. By adjusting the oxidation conditions, a thickness of the oxidized portion of the tunnel dielectric material 125′ may vary within a range of from about 1 nm to about 4 nm, such as from about 1 nm to about 3 nm or from about 2 nm to about 4 nm. Only a portion of the tunnel dielectric material 125′ is oxidized during the oxidation process, controlling the thickness of the oxidized portion. The tunnel dielectric material 125′ may, therefore, exhibit a heterogeneous composition throughout its thickness, with the oxidized portion including a higher concentration of oxygen atoms than the underlying tunnel dielectric material 125 of the first block 110 and the tunnel dielectric material 125 of the second block 115. The oxidized portion (e.g., the oxygen rich portion) exhibits a greater content (e.g., amount) of oxygen relative to the oxygen content of the as-formed tunnel dielectric material 125. By way of example only, the tunnel dielectric material 125′ of the first block 110 and of the second block 115 may include a stoichiometric compound of the material of the tunnel dielectric material 125 on which the oxidized portion is formed. If, for example, the as-formed tunnel dielectric material 125 is a silicon oxynitride material, the oxidized portion may differ in the ratio of silicon:oxygen:nitrogen atoms relative to the as-formed tunnel dielectric material 125 of the tunnel dielectric material 125′.

A removal process may, optionally, be conducted to remove some or all of the oxidized portion of the tunnel dielectric material 125′. The removal process may be conducted by conventional techniques. Then, and as shown in FIG. 11A, a mask 405 is formed adjacent to (e.g., over) the second block 115, as described above for FIG. 5, to protect the charge blocking material 160, the storage nitride material 120, and the tunnel dielectric material 125′ of the second block 115 during subsequent process acts. The mask 405 may be formed of a resist material or a carbon material by conventional techniques. The mask 405 protects the cell materials of the second block 115 while the tunnel dielectric material 125′ within the pillar openings 315 of the first block 110 remains exposed. A removal process is conducted to remove a portion of the tunnel dielectric material 125′ of the first block 110, producing the tunnel dielectric material 125′a in the first block 110. For example, a portion of the oxidized portion of the tunnel dielectric material 125′ of the first block 110 may be removed. Therefore, the tunnel dielectric material 125′a of the first block 110 and the tunnel dielectric material 125′ of the second block 115 differ in the thickness of the oxidized portion 125b remaining on the tunnel dielectric material 125′a. FIG. 11B is an enlarged view of the boxed region of FIG. 11A showing the tunnel dielectric material 125′a including the oxidized portion 125b on the tunnel dielectric material 125′. For simplicity in the drawings, the oxidized portion 125b of the tunnel dielectric material 125′a of the first block 110 is only shown in FIG. 11B. The oxidized portion 125b of the tunnel dielectric material 125′a in the first block 110 has a reduced thickness relative to the thickness of the oxidized portion of the tunnel dielectric material 125′ in the second block 115. As this process stage, the tunnel dielectric material 125′a of the first block 110 and the tunnel dielectric material 125′ of the second block 115 differ in relative thickness, with the thickness of the tunnel dielectric material 125′ being greater than a thickness of the tunnel dielectric material 125′a. The tunnel dielectric material 125′ and the tunnel dielectric material 125′a in the first and second blocks 110, 115 may exhibit substantially the same material composition at this process stage and differ only in thickness, with the oxidized portion 125b being the main difference between the first and second blocks.

One or more oxidation processes may then, optionally, be conducted to produce the tunnel dielectric material 125′ and the tunnel dielectric material 125′a differing in both thickness and material composition. Conducting the additional oxidation processes may enable the different material compositions of the tunnel dielectric material 125′ and the tunnel dielectric material 125′a to be produced. Therefore, the first and second blocks 110, 115 may include tunnel dielectric material 125′ and tunnel dielectric material 125′a differing in both thickness and material composition. The mask 405 may be removed before or after conducting the optional oxidation processes depending on the desired thicknesses and material composition of the tunnel dielectric material 125′ and tunnel dielectric material 125′a. The mask 405 may be removed by conventional techniques. The first and second blocks 110, 115 may, therefore, include tunnel dielectric material 125′ and tunnel dielectric material 125′a differing in thickness, material composition, or both thickness and material composition. Due to the differing oxidation and removal acts in the first block 110 and the second block 115, the oxidized portion 125b of the tunnel dielectric material 125′a may include a higher quality material (e.g., exhibiting fewer defects) than the oxidized portion of the tunnel dielectric material 125′. The tunnel dielectric material 125′a and the tunnel dielectric material 125′ may exhibit heterogeneous compositions throughout their thicknesses, with the oxidized portions exhibiting a higher concentration of oxygen atoms than the underlying portions. By way of example only, the as-formed tunnel dielectric material 125 is a silicon oxynitride material, the oxidized portion and the as-formed portion may differ in the ratio of silicon:oxygen:nitrogen atoms.

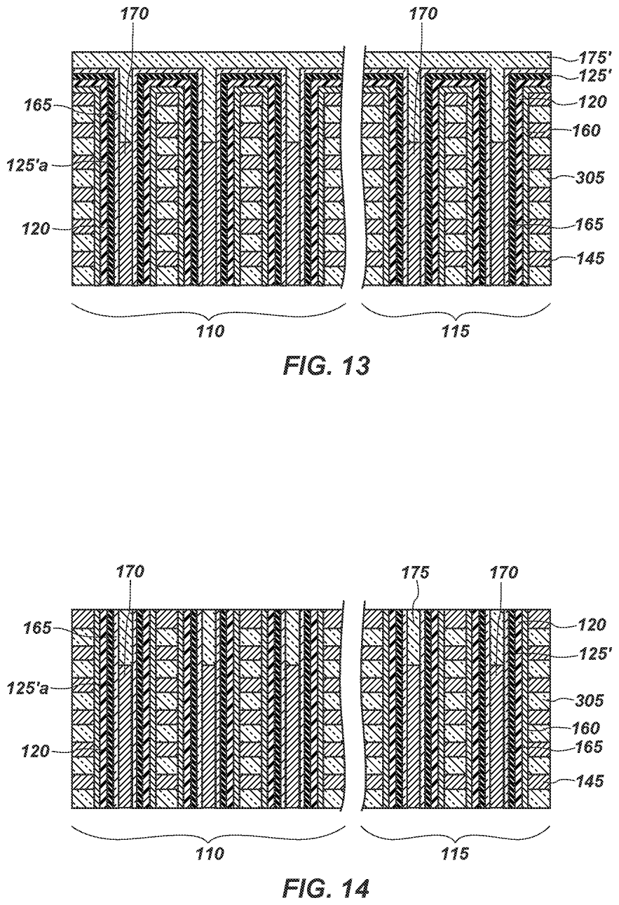

The channel material 165, the fill material 170′, and the conductive material 175′ may be formed in the remaining volume of the pillar openings 315 as shown in FIGS. 12 and 13. The channel material 165 and the fill material 170′ may be formed substantially as described above for FIG. 7. A portion of the fill material 170′ is removed, as described above for FIG. 8, following which the conductive material 175′ is formed adjacent to (e.g., over) the fill material 170. As shown in FIG. 14, a portion of the conductive material 175′ is removed, forming the conductive material 175 over the fill material 170. The desired portion of the conductive material 175′ is removed as described above for FIG. 9. The replacement gate process may be conducted as described above, forming the electronic device 100′ (FIG. 2) including the memory cells 105 with the different material compositions and thicknesses in the memory cells 105 of the first block 110 and the second block 115.

Since the first block 110 includes the tunnel dielectric material 125′a and the second block 115 includes the tunnel dielectric material 125′, the memory cells 105′, 105 of the first and second blocks 110, 115 differ and are configured to exhibit different electrical properties during use and operation of the electronic device 100′ containing the memory cells 105′, 105. By way of example only, the memory cells 105′ of the first block 110 may exhibit different (e.g., improved) programming speed relative to the memory cells 105 of the second block 115, while the memory cells 105 of the second block 115 may have improved cycling endurance relative to the memory cells 105′ of the first block 110.

The electronic devices 100, 100′ include the stacks 135 of alternating conductive materials 140 and dielectric materials 145, with the conductive materials 140 functioning as wordlines (e.g., control gates). The conductive material 140 of the stacks 135 may be a conductive material including, but not limited to, n-doped polysilicon, p-doped polysilicon, undoped polysilicon, or a metal. In some embodiments, the conductive material 140 is tungsten. In other embodiments, the conductive material 140 is n-doped polysilicon. The dielectric material 145 of the stacks 135 may be silicon oxide, silicon nitride, silicon oxynitride, or other dielectric material. In some embodiments, the dielectric material 145 is silicon oxide. The charge blocking material 160 may function as a barrier material between the tiers 150 and the storage nitride material 120, 120′ during use and operation of the electronic devices 100, 100′. The storage nitride material 120, 120′ may function as a charge trap material during use and operation of the electronic devices 100, 100′. The tunnel dielectric material 125, 125′, 125′a may function as a barrier material between the storage nitride material 120, 120′ and the channel material 165 during use and operation of the electronic devices 100, 100′.

Accordingly, an electronic device is disclosed. The electronic device comprises first blocks and second blocks of an array comprising memory cells. The memory cells in the first blocks and in the second blocks comprise memory pillars extending through a stack of alternating dielectric materials and conductive materials. The memory pillars comprise a charge blocking material laterally adjacent to the stack, a storage nitride material laterally adjacent to the charge blocking material, a tunnel dielectric material laterally adjacent to the storage nitride material, a channel material laterally adjacent to the tunnel dielectric material, and a fill material between opposing sides of the channel material. One or more of the storage nitride material and the tunnel dielectric material in the first blocks differ in thickness or in material composition from one or more of the storage nitride material and the tunnel dielectric material in the second blocks.

Accordingly, another electronic device is disclosed and comprises a memory array of a single die, the memory array comprising first blocks and second blocks laterally adjacent to the first blocks. Memory cells of the first blocks are configured to exhibit different electrical properties relative to memory cells of the second blocks. The first blocks comprise pillar regions comprising memory pillars extending through a stack of tiers. Each of the memory pillars comprises a charge blocking material between the tiers and a storage nitride material, the storage nitride material between the charge blocking material and a tunnel dielectric material, and the tunnel dielectric material between the storage nitride material and a channel material. One or more of the storage nitride material or the tunnel dielectric material of the second blocks exhibits a greater thickness than the one or more of the storage nitride material or the tunnel dielectric material of the first blocks.

Accordingly, a method of forming an electronic device is disclosed. The method comprises forming pillar openings in a stack comprising first blocks and second blocks laterally adjacent to the first blocks. A charge blocking material and a storage nitride material are formed in the pillar openings of the first blocks and of the second blocks. A mask material is formed over the second blocks and a portion of the storage nitride material of the first blocks is removed. The mask material is removed from the second blocks. A tunnel dielectric material is formed adjacent to the storage nitride material of the first blocks and of the second blocks. A channel material is formed adjacent to the tunnel dielectric material of the first blocks and of the second blocks and a fill material is formed between opposing portions of the channel material.

Accordingly, a method of forming an electronic device is disclosed. The method comprises forming pillar openings in a stack comprising first blocks and second blocks. A charge blocking material, a storage nitride material, and a tunnel dielectric material are formed in the pillar openings of the first blocks and of the second blocks. A portion of the tunnel dielectric material is oxidized to form an oxidized portion of the tunnel dielectric material. A mask material is formed over the second blocks. A portion of the oxidized portion of the tunnel dielectric material is removed from the first blocks. A channel material is formed adjacent to the tunnel dielectric material of the first blocks and of the second blocks. A fill material is formed between opposing portions of the channel material.

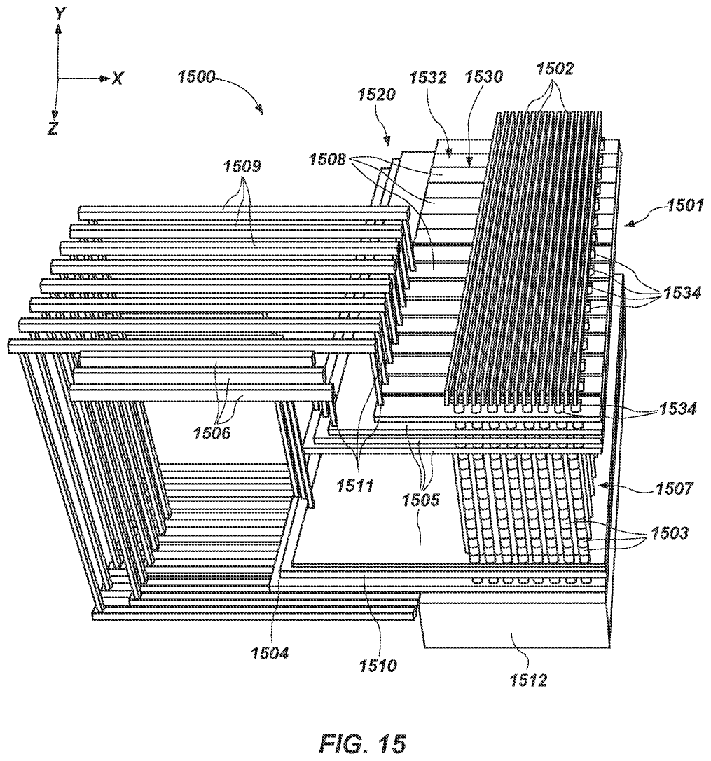

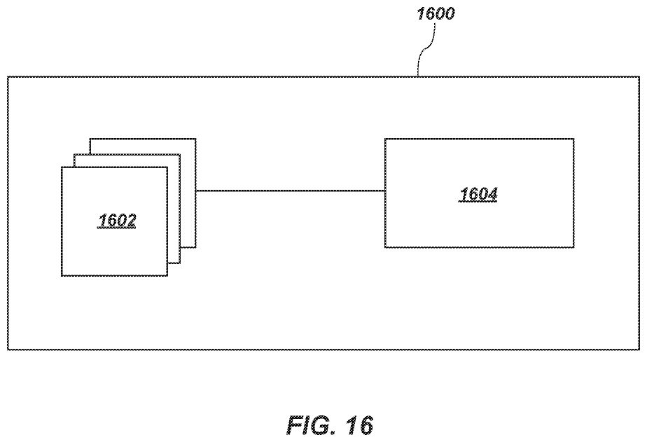

One or more of the electronic devices 100, 100′ according to embodiments of the disclosure may be present in an apparatus (e.g., a memory device), which may be a 3D electronic device, such as a 3D NAND Flash memory device, (e.g., a multideck 3D NAND Flash memory device). FIG. 15 is a partial cutaway, perspective, schematic illustration of a portion of an apparatus 1500 including one or more electronic devices 1501 (corresponding to electronic devices 100, 100′ according to embodiments of the disclosure). The electronic device 1501 may be substantially similar to the embodiments of the electronic devices 100, 100′ described above (e.g., the electronic devices 100, 100′ of FIGS. 1 and 2) and may have been formed by the methods described above. The apparatus 1500 may include a staircase structure 1520 defining contact regions for connecting wordlines 1506 to conductive materials 1505 of tiers. The apparatus 1500 may include vertical strings 1507 that are adjacent to each other in series. The vertical strings 1507 may extend vertically (e.g., in the Z-direction) and orthogonally to bitlines 1502 (e.g., data lines). The apparatus 1500 also includes first select gate drain 1508 (e.g., upper select gates, first select gates, select gate drains (SGDs)), select lines 1509, and a second select gate 1510 (e.g., a lower select gate, a source select gate (SGS)). Vertical conductive contacts 1511 may electrically couple components to each other, as illustrated. The bitlines 1502 may be electrically coupled to the vertical strings 1507 through conductive contact structure (not shown).

The apparatus 1500 may also include a control unit 1512 positioned under the staircase structure 1520. The control unit 1512 may include at least one of string driver circuitry, pass gates, circuitry for selecting gates, circuitry for selecting the bitlines 1502 and the wordlines 1506, circuitry for amplifying signals, and circuitry for sensing signals. The control unit 1512 may be electrically coupled to the bitlines 1505, the wordlines 1506, a source tier 1504, the first select gate drain 1508, and the second select gates 1510, for example. In some embodiments, the control unit 1512 includes CMOS (complementary metal-oxide-semiconductor) circuitry. In such embodiments, the control unit 1512 may be characterized as having a “CMOS under Array” (“CuA”) configuration.

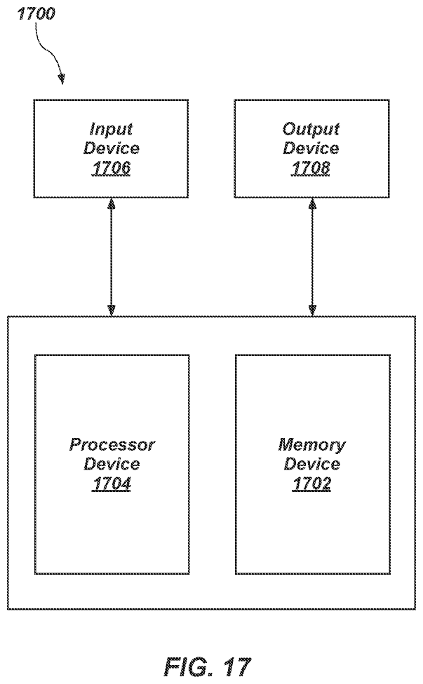

The electronic devices 100, 100′ may be present in a memory array 1600, as shown schematically in FIG. 16. The memory array 1600 includes an array of memory cells 1602 and a control logic component 1604. The memory array 1600 includes the different memory cells 105, 105′ in the first and second blocks 110, 115. The array of memory cells 1602 includes the different memory cells 105, 105′ in, for example, the first and second blocks 110, 115 of the electronic devices 100, 100′ according to embodiments of the disclosure. By way of example only, the memory array 1600 may include the memory cells 105, 105′ in MLC blocks (TLC blocks, QLC blocks, or TLC and QLC blocks) in a so-called “MLC region” and SLC blocks in a so-called “SLC region.” One or more MLC regions and one or more SLC regions may be present in the memory array 1600. The number of SLC blocks may account for a relatively small portion of the total blocks of the memory array 1600 while the MLC blocks (TLC blocks and/or QLC blocks) account for the remainder of the blocks. By way of example only, the SLC blocks may account for less than or equal to about 10% of the total blocks, such as from about 1% to about 5% of the total blocks or from about 5% to about 10% of the total blocks.

The control logic component 1604 may be configured to operatively interact with the memory array of memory cells 105, 105′ so as to read, write, or re-fresh any or all memory cells within the memory array of memory cells 1602. The memory cells 105, 105′ of the memory array 1600 are coupled to access lines, and the access lines are coupled to control gates of the memory cells 105, 105′. A string of memory cells of the memory array 1600 is coupled in series between a source line and a data line (e.g., a bit line). The memory cells 105, 105′ are positioned between the access lines and the data lines. The access lines may be in electrical contact with, for example, the conductive materials 140 of the stacks 135, and the data lines may be in electrical contact with an electrode (e.g., a top electrode) of the stacks 135. The data lines may directly overlie a row or column of the memory cells 105, 105′ and contact the top electrode thereof. Each of the access lines may extend in a first direction and may connect a row of the memory cells 105, 105′. Each of the data lines may extend in a second direction that is at least substantially perpendicular to the first direction and may connect a column of the memory cells 105, 105′. A voltage applied to the access lines and the data lines may be controlled such that an electric field may be selectively applied at an intersection of at least one access line and at least one bit line, enabling the memory cells 105, 105′ to be selectively operated. Additional process acts to form the memory array 1600 including the electronic devices 100, 100′ are conducted by conventional techniques.

The apparatus 1500 including the electronic devices 100 may be used in embodiments of electronic systems of the disclosure. A system 1700 is also disclosed, as shown in FIG. 17, and includes the one or more of the electronic devices 100, 100′ according to embodiments of the disclosure. FIG. 17 is a simplified block diagram of the system 1700 implemented according to one or more embodiments described herein. The system 1700 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The system 1700 includes at least one memory device 1702, which includes the electronic devices 100, 100′ as previously described. The system 1700 may further include at least one processor 1704, such as a microprocessor, to control the processing of system functions and requests in the system 1700. The processor device 1704 and other subcomponents of the system 1700 may include the memory cells.

Various other devices may be coupled to the processor device 1704 depending on the functions that the system 1700 performs. For example, an input device 1706 may be coupled to the processor device 1704 for inputting information into the system 1700 by a user, such as, for example, a mouse or other pointing device, a button, a switch, a keyboard, a touchpad, a light pen, a digitizer and stylus, a touch screen, a voice recognition system, a microphone, a control panel, or a combination thereof. An output device 1708 for outputting information (e.g., visual or audio output) to a user may also be coupled to the processor device 1704. The output device 1708 may include an LCD display, an SED display, a CRT display, a DLP display, a plasma display, an OLED display, an LED display, a three-dimensional projection, an audio display, or a combination thereof. The output device 1708 may also include a printer, an audio output jack, a speaker, etc. In some embodiments, the input device 1706 and the output device 1708 may comprise a single touchscreen device that can be used both to input information to the system 1700 and to output visual information to a user. The one or more input devices 1706 and output devices 1708 may communicate electrically with at least one of the memory device 1702 and the processor device 1704. The at least one memory device 1702 and processor device 1704 may also be used in a system on chip (SoC).

Accordingly, a system is disclosed. The system comprises a processor operably coupled to an input device and an output device, and one or more electronic devices operably coupled to the processor. The one or more electronic devices comprise memory cells in first blocks and in second blocks of a single die. The memory cells comprise memory pillars comprising cell materials. One or more or a storage nitride material or a tunnel dielectric material of the cell materials of the first blocks differs in thickness from the storage nitride material or the tunnel dielectric material, respectively, of the second blocks.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device comprising:
first blocks and second blocks of an array comprising memory cells, the memory cells in the first blocks and in the second blocks comprising:
memory pillars extending through a stack of alternating dielectric materials and conductive materials, the memory pillars comprising a charge blocking material laterally adjacent to the stack, a storage nitride material laterally adjacent to the charge blocking material, a tunnel dielectric material laterally adjacent to the storage nitride material, a channel material laterally adjacent to the tunnel dielectric material, and a fill material between opposing sides of the channel material, one or more of the storage nitride material and the tunnel dielectric material in the first blocks differing in thickness or in material composition from one or more of the storage nitride material and the tunnel dielectric material in the second blocks.

2. The electronic device of claim 1, wherein the memory cells in the first blocks are configured as multilevel memory cells.

3. The electronic device of claim 1, wherein the memory cells in the second blocks are configured as single level memory cells.

4. The electronic device of claim 1, wherein the thickness of the storage nitride material in the memory cells of the first blocks differs from the thickness of the storage nitride material in the memory cells of the second blocks.

5. The electronic device of claim 4, wherein the thickness of the storage nitride material in the memory cells of the first blocks is less than the thickness of the storage nitride material in the memory cells of the second blocks.

6. The electronic device of claim 4, wherein a difference in thickness of the storage nitride material in the memory cells of the first blocks and the thickness of the storage nitride material in the memory cells of the second blocks is between about 1 nm and about 4 nm.

7. The electronic device of claim 4, wherein the storage nitride material in the memory cells of the first blocks and in the memory cells of the second blocks comprises silicon nitride.

8. The electronic device of claim 4, wherein the storage nitride material in the memory cells of the first blocks and in the memory cells of the second blocks comprises silicon oxynitride.

9. The electronic device of claim 1, wherein a material composition of the tunnel dielectric material in the memory cells of the first blocks is different than a material composition of the tunnel dielectric material in the memory cells of the second blocks.

10. The electronic device of claim 9, wherein the material composition of the tunnel dielectric material in the memory cells of the second blocks comprises silicon oxynitride or silicon nitride, and the material composition of the tunnel dielectric material in the memory cells of the first blocks comprises an upper, oxidized portion.

11. The electronic device of claim 1, wherein the memory cells of the first blocks and the memory cells of the second blocks are present on a single die.

12. An electronic device comprising:
a memory array of a single die, the memory array comprising first blocks and second blocks laterally adjacent to the first blocks, memory cells of the first blocks configured to exhibit different electrical properties relative to memory cells of the second blocks,
the first blocks comprising pillar regions comprising memory pillars extending through a stack of tiers, each of the memory pillars comprising a charge blocking material between the tiers and a storage nitride material, the storage nitride material between the charge blocking material and a tunnel dielectric material, and the tunnel dielectric material between the storage nitride material and a channel material; and
the second blocks comprising pillar regions comprising memory pillars extending through the stack of tiers, each of the memory pillars comprising the charge blocking material between the tiers and the storage nitride material, the storage nitride material between the charge blocking material and the tunnel dielectric material, and the tunnel dielectric material between the storage nitride material and the channel material, one or more of the storage nitride material and the tunnel dielectric material of the second blocks exhibiting a greater thickness than the one or more of the storage nitride material or the tunnel dielectric material of the first blocks.

13. The electronic device of claim 12, wherein the tunnel dielectric material of the second blocks exhibits a different material composition than the tunnel dielectric material of the first blocks.

14. The electronic device of claim 12, wherein the charge blocking material, the storage nitride material, and the tunnel dielectric material are coextensive with a height of the stack of tiers.

15. The electronic device of claim 12, wherein the channel material is coextensive with a height of the stack of tiers.

16. The electronic device of claim 12, wherein the one or more of the storage nitride material or the tunnel dielectric material of the second blocks exhibits a different material composition than the one or more of the storage nitride material or the tunnel dielectric material of the second blocks.

17. A method of forming an electronic device, comprising:
forming pillar openings in a stack comprising first blocks and second blocks laterally adjacent to the first blocks;
forming a charge blocking material and a storage nitride material in the pillar openings of the first blocks and of the second blocks;
forming a mask material over the second blocks;
removing a portion of the storage nitride material of the first blocks;
removing the mask material from the second blocks;
forming a tunnel dielectric material adjacent to the storage nitride material of the first blocks and of the second blocks;
forming a channel material adjacent to the tunnel dielectric material of the first blocks and of the second blocks; and
forming a fill material between opposing portions of the channel material.

18. The method of claim 17, wherein forming a charge blocking material and a storage nitride material in the pillar openings comprises conformally forming the charge blocking material on sidewalls of the stack and conformally forming the storage nitride material on the sidewalls of the charge blocking material.

19. The method of claim 17, wherein forming a mask material over the second blocks comprises forming the mask material over the second blocks without forming the mask material over the first blocks.

20. The method of claim 17, wherein removing a portion of the storage nitride material of the first blocks comprises decreasing a thickness of the storage nitride material of the first blocks without decreasing a thickness of the storage nitride material of the second blocks.

21. The method of claim 17, wherein removing a portion of the storage nitride material of the first blocks comprises removing from about 1 nm to about 4 nm of the storage nitride material from the first blocks.

22. A method of forming an electronic device, comprising:
forming pillar openings in a stack comprising first blocks and second blocks laterally adjacent to the first blocks;
forming a charge blocking material, a storage nitride material, and a tunnel dielectric material in the pillar openings of the first blocks and of the second blocks;
oxidizing a portion of the tunnel dielectric material to form an oxidized portion of the tunnel dielectric material in the first blocks and the second blocks;
forming a mask material over the second blocks;
removing a portion of the oxidized portion of the tunnel dielectric material from the first blocks;
forming a channel material adjacent to the tunnel dielectric material of the first blocks and of the second blocks; and
forming a fill material between opposing portions of the channel material.

23. The method of claim 22, further comprising removing a portion of the tunnel dielectric material before forming the mask material over the second blocks.

24. The method of claim 22, wherein removing a portion of the oxidized portion of the tunnel dielectric material from the first blocks comprises forming the tunnel dielectric material in the first blocks exhibiting a different thickness than the tunnel dielectric material in the second blocks.

25. The method of claim 22, further comprising oxidizing an additional portion of the tunnel dielectric material to form the tunnel dielectric material of the first blocks exhibiting a different composition than the tunnel dielectric material of the second blocks.

26. A system, comprising:
a processor operably coupled to an input device and an output device; and
one or more electronic devices operably coupled to the processor, the one or more electronic devices comprising memory cells in first blocks and in second blocks of a single die, the memory cells comprising:
memory pillars comprising cell materials, one or more of a storage nitride material or a tunnel dielectric material of the cell materials of the first blocks differing in thickness from the thickness of the storage nitride material or the tunnel dielectric material, respectively of the second blocks.
